(19) United States
(12) Patent Application Publication
(10) Pub. No.: US 2008/0048339 A1
(43) Pub. Date: Feb. 28, 2008

(54) Metal line structures and methods of forming the same

(75) Inventors: Jeong-Hoon Ahn, Yongin-si (KR); Heon-Jong Shin, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/892,226

(22) Filed: Aug. 21, 2007

(30) Foreign Application Priority Data
Aug. 22, 2006 (KR) 10-2006-0079538

(51) Int. Cl. H01L 23/528; H01L 21/4763

(52) U.S. Cl. 257/774; 438/627; 257/E23.151; 257/E21.495

(57) ABSTRACT

Example embodiments may provide metal line structures, and example methods may include forming the same. Example embodiment metal line structures may include a first metal line on a substrate, a first barrier metal layer on sidewalls and a lower surface of the first metal line, a first insulating layer covering the first metal line, a second metal line on the first insulating layer, a contact plug passing through the first insulating layer to electrically connect the first metal line and the second metal line, and a second barrier metal layer on sidewalls and a lower surface of the contact plug and the second metal line. The first barrier metal layer and the second barrier metal layer may contact each other.

### PRIORITY STATEMENT

This application claims priority under 35 USC § 119 to Korean Patent Application No. 2006-79538, filed on Aug. 22, 2006, in the Korean Intellectual Property Office (KIPO), the entire contents of which are incorporated herein by reference.

### BACKGROUND

Example embodiments relate to semiconductor integrated circuits, for example, to metal lines and methods of forming metal lines.

Due to increased semiconductor device integration and miniaturization, defects in and/or deterioration of miniaturized electric lines may occur. Deterioration of lines due to electromigration may present a problem for further integration and miniaturization.

Related art integrated circuits may include multi-layered lines and/or contact plugs electrically connecting the multi-layered lines. Related art semiconductor integrated circuits may include a lower line, an upper line, and/or a contact plug. The contact plug may electrically connect the lower line with the upper line. The upper line and/or the lower line may have a barrier metal layer on their sidewalls and/or lower surfaces. The contact plug may contact the upper surface of the lower line.

If current flows from the lower line to the upper line, electrons may migrate from the upper line to the lower line, and electromigration may occur in the lower line. That is, metal atoms (e.g., Al and/or Cu atoms) in the lower line may migrate in the direction of electron movement, and an empty space may be formed on the lower line that may contact the contact plug. Electromigration may cause the line to become electrically disconnected, which may reduce reliability of an integrated circuit.

Furthermore, the upper surface of the line may be previously damaged due to etching while forming the lines, and thus electromigration may compound this damage such that the reliability of the lines may be further reduced.

### SUMMARY

Example embodiments may provide metal line structures with improved reliability and methods of forming the same.

Example embodiment metal line structures may include a first metal line on a substrate, a first barrier metal layer on sidewalls and/or a lower surface of the first metal line, a first insulating layer on the first metal line, a second metal line on the first insulating layer, a contact plug passing through the first insulating layer to electrically connect the first metal line and the second metal line, and/or a second barrier metal layer on sidewalls and/or a lower surface of the contact plug and/or sidewall and/or lower surface of the second metal line. The first barrier metal layer and the second barrier metal layer may contact each other.

Sidewalls of the first metal line and sidewalls of the second metal line may be on the same side surface.

Example embodiment metal line structures may further include a second insulating layer on the first insulating layer. The contact plug may be in the first insulating layer, and the second metal line may be in the second insulating layer. The metal line may further include a first etch stop layer between the substrate and the first insulating layer and/or a second etch stop layer between the first insulating layer and the second insulating layer. The metal line may further include another contact plug spaced apart from the contact plug and electrically connecting the first metal line and the second metal line.

Example embodiment metal line structures may further include another contact plug spaced apart from the contact plug and electrically connecting the first metal line and the second metal line.

The first metal line may extend in a first direction, and the contact plug may have a width in the first direction greater than a width in a second direction, the second direction being substantially perpendicular to the first direction.

Example methods of forming a metal line structure may include forming a first metal line on a substrate and a first barrier metal layer on sidewalls and/or a lower surface of the first metal line, forming an insulating layer on the first metal line and/or the first barrier metal layer, forming a first via hole exposing the first metal line and/or the first barrier metal layer in the insulating layer, forming a second barrier metal layer contacting the exposed first barrier metal layer in sidewalls and/or a lower surface of the first via hole, and forming a first contact plug in the first via hole and a second metal line electrically connected to the first contact plug on the insulating layer.

Example methods may include aligning sidewalls of the first via hole with the first barrier metal layer.

Forming the first via hole may include forming a second via hole apart from the first via hole exposing the first metal line. Forming the first contact plug may include forming a second contact plug in the second via hole. The second metal line may be electrically connected to the second contact plug.

The first metal line may extend toward a first direction, and the first via hole may have a width of the first direction broader than a width of a second direction, the second direction perpendicular to the first direction. The width in the first direction may be more than twice the width of the second direction.

Example methods may further include forming a first etch stop layer between the substrate and the first insulating layer and forming a second etch stop layer between the first insulating layer and the second insulating layer.

### BRIEF DESCRIPTION OF THE FIGURES

The above and/or other aspects and advantages will become more apparent and more readily appreciated from the following detailed description of example embodiments taken in conjunction with the accompanying drawings, in which:

FIG. 1 is a plan view of an example embodiment metal line structure according;

FIG. 2 is a profile view taken along line I-I′ of FIG. 1;

FIG. 3 is a plan view of an example embodiment metal line structure;

FIG. 4 is a profile view taken along line II-II′ of FIG. 3;

FIG. 5 is a plan view of an example embodiment metal line structure;

FIG. 6 is a profile view taken along line III-III′;

FIGS. 7 through 9 are profile views taken along line I-I′ of FIG. 1 illustrating example methods of forming a metal line;

FIGS. 10 and 11 are profile views taken along line II-II′ of FIG. 3 illustrating example methods of forming a metal line; and

FIGS. 12 and 13 are profile views taken along line 111-1111′ of FIG. 5 illustrating example methods of forming a metal line.

### DETAILED DESCRIPTION

Example embodiments will now be described more fully with reference to the accompanying drawings. Embodiments, however, may be embodied in many different forms and should not be construed as being limited to example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

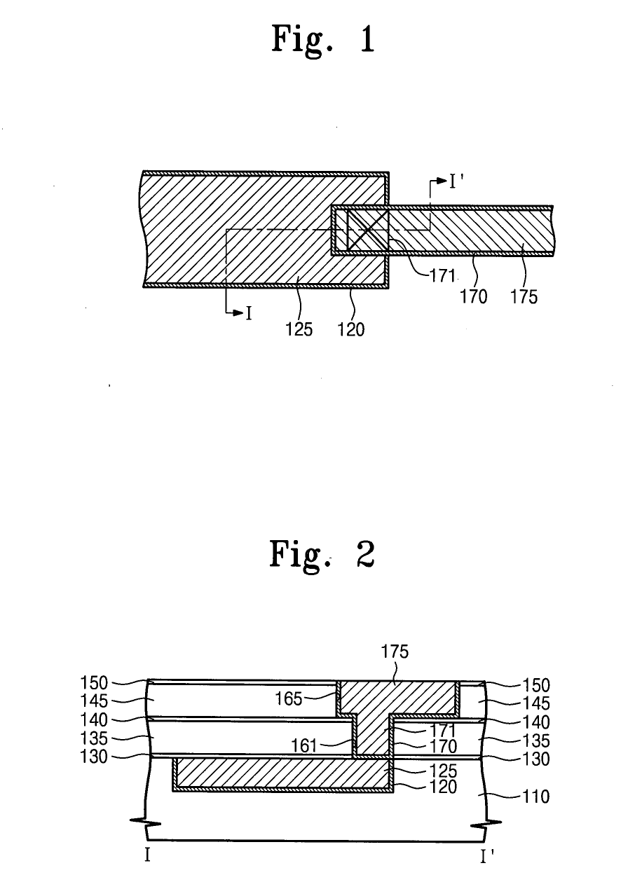

### Example Embodiments in FIGS. 1-2

FIG. 1 is a plan view of an example embodiment metal line structure. FIG. 2 is a profile view taken along line I-I′ of FIG. 1.

As shown in FIGS. 1 and 2, a first metal line 125 may be on a substrate 110. A first barrier metal layer 120 may be on sidewalls and/or a lower surface of the first metal line 125. The first metal line 125 may be electrically connected to a transistor, a line, and/or another electrical structure (not shown) below the substrate 110. The first metal line 125 may include materials such as Cu, Al, and/or another suitable line material. The first barrier metal layer 120 may prevent or reduce metal material of the first metal line 125 from diffusing and may include materials such as Ti, TiN, Ta, TaN, and/or another suitable barrier metal material having littler or no atomic migration due to electromigration.

A first etch stop layer 130, a first insulating layer 135, a second etch stop layer 140, a second insulating layer 145, and/or a third etch stop layer 150 may be stacked on the first metal line 125 and the first barrier metal layer 120. The first, second, and third etch stop layers 130, 140, and 150 may include SiN, SiC, SiCN, and/or another suitable material. The first, second, and third/or etch stop layers 130, 140, and 150 may prevent or reduce a lower layer from being damaged during an etching process and may serve as a diffusion blocking layer that blocks metal materials of the lines 125 and 175 from diffusing into, on, and/or below the first, second, and third etch stop layers 130, 140, and 150. The first and/or second insulating layers 135 and 145 may be interlayer dielectrics and/or intermetal dielectrics, and may include SiO₂, SiOF, SiOC, and/or other suitable dielectrics. The first etch stop layer 130, a second etch stop layer 140, and/or the first insulating layer 135 may include a via hole 161 to expose the first metal line 125 and/or the first barrier metal layer 120. The third etch stop layer 150 and the second insulating layer 145 may include a trench 165 that may be connected to the via hole 161.

A contact plug may be in the via hole 161 of the first insulating layer 135, and a second metal line 175 may be in the trench 165 of the second insulating layer 145. The contact plug 171 may electrically connect the first metal line 125 to the second metal line 175. The second metal line 175 and the contact plug 171 may include Cu, Al, and/or another suitable conductor.

A second barrier metal layer 170 may be on sidewalls and/or a lower surface of the via hole 161 and trench 165. Alternatively, the second barrier metal layer 170 may be on sidewalls and/or the lower surface of the contact plug 171 and second metal line 175. The second barrier metal layer 170 may contact the first barrier metal layer 120. The contact area of the first metal line 125 and the contact plug 171 may be increased to reduce resistance between the lines 125 and 175. A sidewall of the via hole 161 may be aligned with the first barrier metal layer 120 on sidewalls of the first metal line 125, and the second metal line 175 may contact the first barrier metal layer 120 on sidewalls of the first metal line 125. That is, the first barrier metal line 120 and the second barrier metal line 170 may be on a same side of the first metal line 125 and contact plug 161. The second barrier metal layer 170 may prevent or reduce metal materials in the second metal line 175 and the contact plug 171 from diffusing and may include materials such as Ti, TiN, Ta, TaN, and/or another suitable material having reduced or no atomic migration due to electromigration.

If empty space due to electromigration on the first metal line 125 contacting the contact plug 171 does occur, electrons may still flow through the first barrier metal layer 120 and the second barrier metal layer 170 that contact each other and maintain an electrical connection between the first metal line 125 and the second metal line 175.

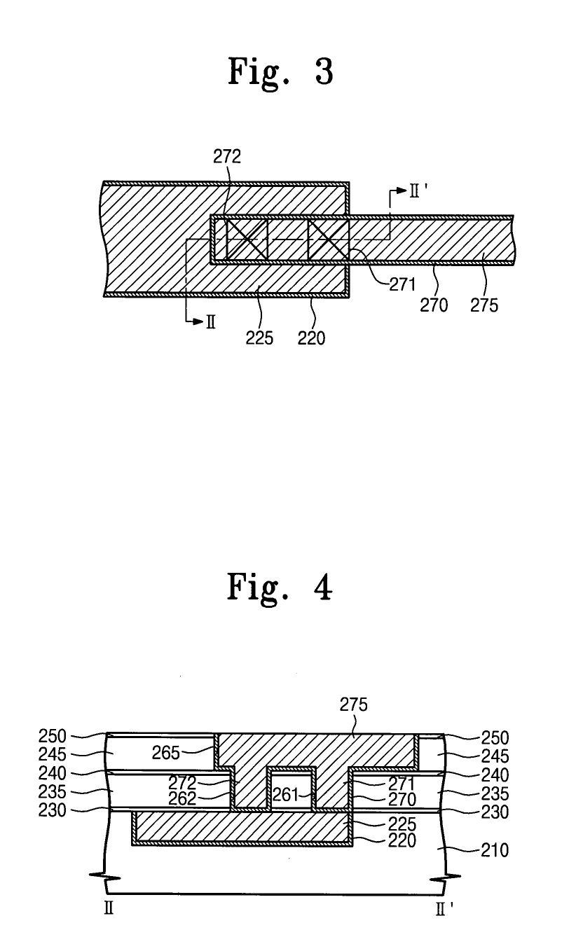

### Example Embodiments in FIGS. 3-4

FIG. 3 is a plan view of an example embodiment metal line structure. FIG. 4 is a profile view taken along line II-II′ of FIG. 3. Descriptions overlapping with previously described example embodiments may be omitted below.

As shown in FIGS. 3 and 4, a first metal line 225 may be on a substrate 210. A first barrier metal layer 220 may be on sidewalls and/or a lower surface of the first metal line 225. A first etch stop layer 230, a first insulating layer 235, a second etch stop layer 240, a second insulating layer 245, and a third etch stop layer 250 may be stacked on the first metal line 225 and the first barrier metal layer 220.

The first etch stop layer 230, the second etch stop layer 240, and the first insulating layer 235 may include a first via hole 261 and/or a second via hole 262. The first via hole 261 may expose the first metal line 225 and/or the first barrier metal layer 220. The second via hole 262 may expose the first metal line 225. The third etch stop layer 250 and/or the second insulating layer 245 may include a trench 265 that may electrically connect the first metal line 225 with the second metal line 275.

The second barrier metal layer 270 may be on sidewalls and/or lower surfaces of the first and/or second via holes 261 and 262, and the second barrier metal layer 270 may be on sidewalls and/or a lower surface of the trench 265. That is, the second barrier metal layer 270 may be on sidewalls and/or lower surfaces of the first and second contact plugs 271 and 272 and the second metal line 275. The second barrier metal layer 270 may contact the first barrier metal layer 220. Sidewalls of the first via hole 261 may be aligned with the first barrier metal layer 220 on sidewalls of the first metal line 225, and the second barrier metal layer 270 may be on sidewalls of the first via hole 261 so as to contact the first barrier metal layer 220 on sidewalls of the first metal line 225. Thus, the first barrier metal layer 220 and the second barrier metal layer 270 may share a similar sidewall.

Example embodiments may prevent or reduce electromigration and thereby increase line reliability. The resistance of the metal line may be reduced by forming a plurality of spaced apart contact plugs 271 and 272.

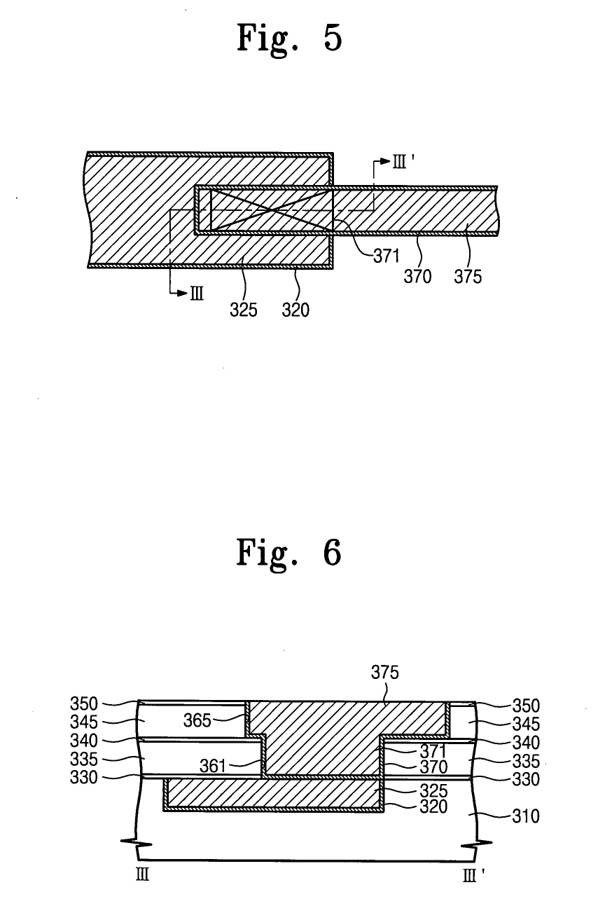

### Example Embodiments in FIGS. 5-6

FIG. 5 is a plan view of an example embodiment metal line structure. FIG. 6 is a profile view taken along line III-III′. Descriptions overlapping with previously described example embodiments may be omitted below.

As shown in FIGS. 5 and 6, a first metal line 325 may be on a substrate 310. A first barrier metal layer 320 may be on sidewalls and/or a lower surface of the first metal line 325. A first etch stop layer 330, a first insulating layer 335, a second etch stop layer 340, a second insulating layer 345, and a third etch stop layer 350 may be stacked on the first metal line 325 and/or the first barrier metal layer 320.

The first etch stop layer 330, the second etch stop layer 340, and/or the first insulating layer 335 may include a via hole 361 exposing the first metal line 325 and/or the first barrier metal layer 320. The third etch stop layer 350 and/or the second insulating layer 345 may include a trench 365 connected to the via hole 361. The via hole 361 may extend in a first in which the first metal line 325 extends. The via hole 361 may have a width in the first direction broader a width in a second direction perpendicular to the first direction. The width in the first direction may be more than twice than the width in the second direction.

A contact plug 371 may be in the via hole 361 of the first insulating layer 335, and a second metal line 375 may be in the trench 365 of the second insulating layer 345. Because the contact plug 371 may be in the via hole 361, it may have a width in the first direction broader a the width in the second direction perpendicular to the first direction. The width in the first direction may be more than twice the width in the second direction. The contact plug 371 may electrically connect the first metal line 325 with the second metal line 375.

The second barrier metal layer 370 may be on sidewalls and/or a lower surface of the via hole 361 and the trench 365. That is, the second barrier metal layer 370 may be on sidewalls and/or a lower surface of the contact plug 371 and the second metal line 375. The second barrier metal layer 370 may contact the first barrier metal layer 320. Sidewalls of the via hole 361 may be aligned with the first barrier metal layer 320 on sidewalls of the first metal line 325. The first barrier metal layer 320 and the second barrier metal layer 370 may share a similar sidewall.

Example embodiments may prevent or reduce electromigration and thereby increase the reliability of the metal lines. Additionally, contact area of the contact plug 371 and the first metal line 325 may be increased such that the resistance of the metal line can be reduced and the contact plug 371 and the first metal line 325 may be aligned.

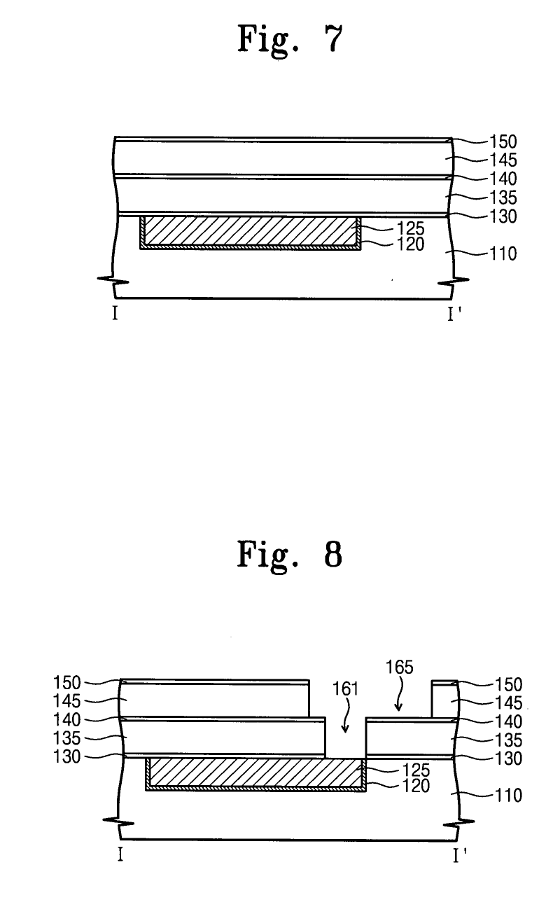

### Example Methods of FIGS. 7-9

FIGS. 7 through 9 are profile views taken along line I-I′ of FIG. 1 illustrating example methods of forming metal lines.

As shown in FIG. 7, a first metal line 125 and/or a first barrier metal layer 120 may be formed in a substrate 110. The first barrier metal layer 120 may be formed on sidewalls and/or a lower surface of the first metal line 125. The first metal line 125 may be formed of Cu, Al, and/or another suitable line material, and the first barrier metal layer 120 may be formed on Ti, TiN, Ta, TaN, and/or another suitable barrier metal.

A first etch stop layer 130, a first insulating layer 135, a second etch stop layer 140, a second insulating layer 145, and a third etch stop layer 150 may be formed in a stack on the substrate 110. The first and second insulating layers 135 and 145 may be formed of SiO₂, SiOF, SiOC, and/or another suitable insulator. The first, second, and third etch stop layers 130, 140, and 150 may be formed of SiN, SiC, SiCN, and/or another suitable material having etch selectivity with respect to the first insulating layer 135 and/or the second insulating layer 145.

As shown in FIG. 8, a via hole 161 may be formed in the first insulating layer 135 to expose the first metal line 125 and/or the first barrier metal layer 120, and a trench 165 may be formed in the second insulating layer 145 to connect to the via hole.161. The via hole 161 may be formed first and then the trench 165 may be formed, or the trench 165 may be formed first and then the via hole 161 may be formed. Sidewalls of the via hole 161 may be aligned with the first barrier metal layer 120.

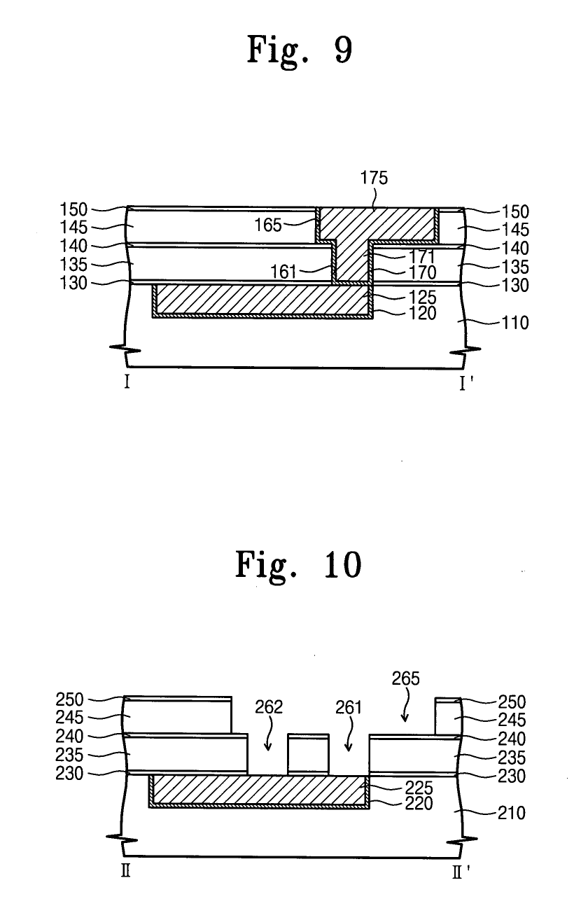

As shown in FIG. 9, a second barrier metal layer 170 may be formed on sidewalls and a lower surface of the via hole 161 and the trench 165. The second barrier metal layer 170 may contact the first barrier metal layer 120. The second barrier metal layer 170 may be formed of Ti, TiN, Ta, TaN, and/or another suitable barrier material. A contact plug 171 may be formed in the via hole 161, and a second metal line 175 may be formed in the trench 165. The contact plug 171 and the second metal line 175 may be formed of Cu, Al, and/or another suitable material.

The second barrier metal layer 170, the contact plug 171, and/or the second metal line 175 may be formed by performing a planarization process for exposing the third etch stop layer 150 after metal layers are formed on the surface of the insulating layers having the via hole 161 and the trench 165.

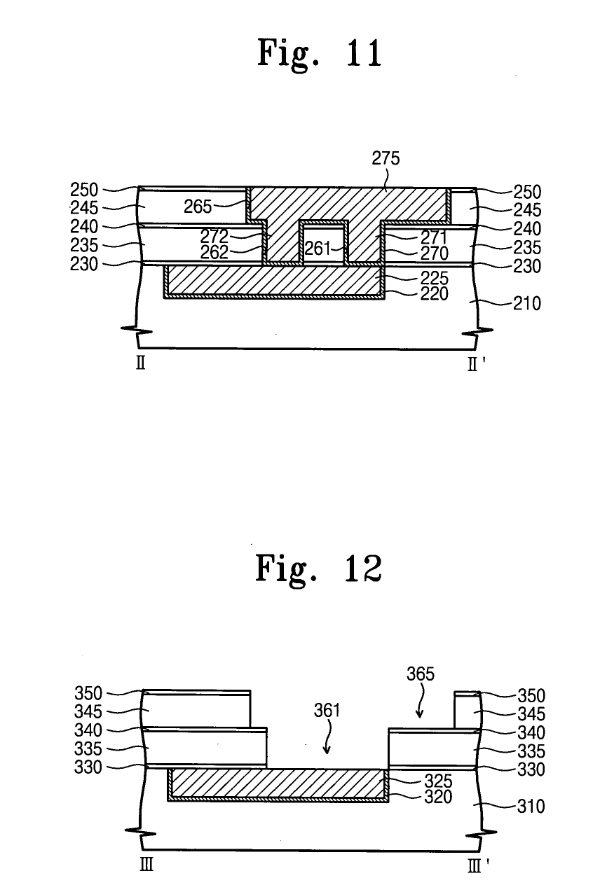

### Example Methods of FIGS. 10-11

FIGS. 10 and 11 are profile views taken along line II-II′ of FIG. 2 illustrating example methods of forming a metal line. Descriptions overlapping with previously described example methods may be omitted below.

As shown in FIG. 10, a first via hole 261 exposing the first metal line 225 and/or the first barrier metal layer 220 and a second via hole 262 exposing the first metal line 225 may be formed in the first insulating layer 235. A trench 265 may be formed in the second insulating layer 245 to connect to the first and second via holes 261 and 262. The first and second via holes 261 and 262 may be formed first, followed by the trench 265, or the trench 265 may be formed first and then the first and second via holes 261 and 262 may be formed. Sidewalls of the first via hole 261 may be aligned with the first barrier metal layer 220 formed on sidewalls of the first metal line 225.

As shown in FIG. 11, the second barrier metal layer 270 may be formed on sidewalls and/or lower surfaces of the first and second via holes 261 and 262, and sidewalls of the lower surface of the trench 265. The second barrier metal layer 270 formed on sidewalls of the first via hole 261 may contact the first barrier metal layer 220 formed on sidewalls of the first metal line 225. The first contact plug 271 may be formed in the first via hole 261, and the second contact plug 272 may be formed in the second via hole 262. The second metal line 275 may be formed in the trench 265. Because a plurality of spaced contact plugs may be formed, the resistance of the metal line may be reduced.

The second barrier metal layer 270, the first and second contact plugs 271 and 272, and/or the second metal line 275 may be formed by performing a planarization process for exposing the third etch stop layer 250, after the metal layers are formed on the insulation layers having the first and second via holes 261 and 262, and the trench 265.

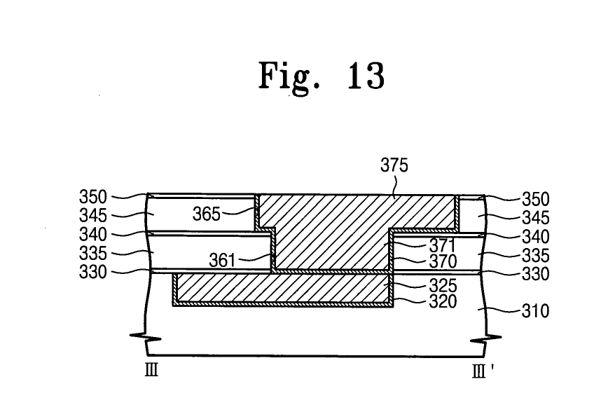

### Example Methods of FIGS. 12-13

FIGS. 12 and 13 are profile views taken along line 111-1111′ of FIG. 3 illustrating example methods of forming a metal line. Descriptions overlapping with previously described example methods may be omitted below.

As shown in FIG. 12, a via hole 361 may be formed in the first insulating layer 335 to expose the first metal line 325 and/or the first barrier metal layer 320. A trench 365 may be formed in the second insulating layer 345 to connect to the via hole 361. The via hole 361 may be formed first and then the trench 365 may be formed, or the trench 365 may be formed first and then the via hole 361 may be formed. Sidewalls of the via hole 361 may be aligned with the first barrier metal layer 320 formed on sidewalls of the first metal line 325. The via hole 361 may extend in a first direction in which the first metal line 325 extends. That is, the via hole 361 may have a width in the first direction broader than a width in a second direction perpendicular to the first direction. At this point, the width of the first direction may be more than twice the width of the second direction.

As shown in FIG. 13, a second barrier metal layer 370 may be formed on sidewalls and a lower surface of the via hole 361 and the trench 365. The second barrier metal layer 370 formed on sidewalls of the via hole 361 may contact the first barrier metal layer 320 formed on the first meal line 325. Next the contact plug 371 may be formed in the via hole 361, and the second metal line 375 may be formed in the trench 365. Because the contact plug 371 may be formed in the via hole 361, it may have a width in the first direction that may be broader than a width in the second direction perpendicular to the first direction. The width in the first direction may be more than twice the width in the second direction. The contact area of the contact plug 371 and the first metal line 325 may be increased such that resistance of the metal line may be reduced.

The second barrier metal layer 370, the contact plug 371, and the second metal line 375 may be formed by performing a planarization process for exposing the third etch stop layer 350, after the metal layers are formed on the insulating layers having the via hole 361 and the trench 365.

Example embodiments may have increased reliability of metal lines by preventing or reducing electromigration. Because the contact plugs may have various configurations, resistance between the metal lines may be reduced, and alignment between the metal line and the contact plug may be obtained.

While example embodiments have been particularly shown and described, it will be understood by those of ordinary skill in the art that various changes in form and details may be made therein without departing from the spirit and scope of the present invention as defined by the following claims.

What is claimed is:

1. A metal line structure comprising:
a first metal line;
a first barrier metal layer on at least one sidewall of the first metal line and on a lower surface of the first metal line;
a first insulating layer on the first metal line;
a second metal line on the first insulating layer;
at least one contact plug passing through the first insulating layer and electrically connecting the first metal line and the second metal line; and
a second barrier metal layer on at least one sidewall and on a lower surface of the at least one contact plug and the second metal line, the first barrier metal layer and the second barrier metal-layer being electrically connected.

2. The metal line structure of claim 1, wherein the at least one sidewall of the first metal line and the at least one sidewall of the contact plug are coplanar.

3. The metal line structure of claim 1, further comprising:
a second insulating layer on the first insulating layer, wherein the at least one contact plug is in the first insulating layer, and the second metal line is in the second insulating layer.

4. The metal line structure of claim 3, further comprising:
a substrate on which the first metal line and the first insulating layer are positioned;
a first etch stop layer between the substrate and the first insulating layer; and
a second etch stop layer between the first insulating layer and the second insulating layer.

5. The metal line structure of claim 1, wherein the at least one contact plug is a plurality of contact plugs, each of the contact plugs being spaced apart from each other and electrically connecting the first metal line and the second metal line.

6. The metal line structure of claim 1, wherein the first metal line extends in a first direction and wherein a width of the contact plug in a first direction is larger than a width of the contact plug in a second direction, the second direction being perpendicular to the first direction.

7. The metal line structure of claim 6, wherein the width in the first direction is more than about twice the width in the second direction.

8. The metal line structure of claim 1, wherein the first barrier metal layer and the second barrier metal layer contact each other.

9. A method of forming a metal line structure, the method comprising:
forming a first metal line on a substrate;
forming a first barrier metal layer on at least one sidewall and on a lower surface of the first metal line;
forming an insulating layer on the first metal line and the first barrier metal layer;
forming at least one via hole in the insulating layer so as to expose at least a portion of the first metal line and the first barrier metal layer;
forming a second barrier metal layer contacting the portion of the first barrier metal layer;
forming at least one contact plug in the first via hole; and
forming a second metal line on the insulating layer, the second metal line being electrically connected to the at least one contact plug.

10. The method of claim 9, further comprising:
aligning a sidewall of the at least one via hole with a sidewall of the first barrier metal layer.

11. The method of claim 9, wherein,
forming the at least one via hole includes forming a plurality of via holes exposing the first metal line, each of the via holes being spaced apart from each other, and
forming the at least one contact plug includes forming a plurality of second contact plugs, each of the contact plugs being in one of via holes.

12. The method of claim 9, wherein the first metal line extends in a first direction, and wherein a width of the at least one via hole in the first direction is larger than a width of a width of the at least one via hole in a second direction, the second direction being substantially perpendicular to the first direction.

13. The method of claim 12, wherein the width in the first direction is more than about twice the width in the second direction.

14. The method of claim 9, further comprising:
forming a first etch stop layer between the substrate and the first insulating layer; and
forming a second etch stop layer between the first insulating layer and the second insulating layer.
